(19) United States
(12) Patent Application Publication
(10) Pub. No.: US 2016/0109496 A1
(43) Pub. Date: Apr. 21, 2016

(54) MEASUREMENT METHOD AND MEASUREMENT SYSTEM

(71) Applicant: FUJITSU LIMITED, Kawasaki-shi (JP)

(72) Inventors: Masakazu Kishi, Kawasaki (JP); Hajime Kubota, Kawasaki (JP); Masayuki ITOH, Kawasaki (JP)

(21) Appl. No.: 14/810,636

(22) Filed: Jul. 28, 2015

(30) Foreign Application Priority Data
Oct. 20, 2014 (JP) 2014-213611

(51) Int. Cl. G01R 23/02; G01R 31/28; G01N 25/00

(52) U.S. Cl. CPC G01R 23/02; G01N 25/00; G01R 31/2824

(57) ABSTRACT

A measurement method includes: obtaining a first temperature characteristic of a crystal oscillator based on a plurality of oscillating frequencies observed when the crystal oscillator is temporarily energized at each of a plurality of temperatures around the crystal oscillator; observing a first oscillating frequency obtained by maintaining energization of the crystal oscillator after setting the temperature around the crystal oscillator to a first temperature of the plurality of temperatures; obtaining a second temperature characteristic of a oscillating frequency when energization of the crystal oscillator is maintained based on the first temperature characteristic and the first oscillating frequency; and normalizing the first temperature characteristic at a given temperature.

### CROSS-REFERENCE TO RELATED APPLICATION

This application is based upon and claims the benefit of priority of the prior Japanese Patent Application No. 2014-213611, filed on Oct. 20, 2014, the entire contents of which are incorporated herein by reference.

### FIELD

The embodiment discussed herein is related to a measurement method and a measurement system.

### BACKGROUND

Due to improved performance of electronic devices, various crystal oscillators used in the electronic devices have been proposed.

The related arts are disclosed in Japanese Laid-open Patent Publication No. 2014-107715 and Japanese Laid-open Patent Publication No. 2013-150120.

### SUMMARY

According to an aspect of the embodiments, a measurement method includes: obtaining a first temperature characteristic of a crystal oscillator based on a plurality of oscillating frequencies observed when the crystal oscillator is temporarily energized at each of a plurality of temperatures around the crystal oscillator; observing a first oscillating frequency obtained by maintaining energization of the crystal oscillator after setting the temperature around the crystal oscillator to a first temperature of the plurality of temperatures; obtaining a second temperature characteristic of a oscillating frequency when energization of the crystal oscillator is maintained based on the first temperature characteristic and the first oscillating frequency; and normalizing the first temperature characteristic at a given temperature.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates an example of a measurement device;

FIG. 2 illustrates an example of an internal structure of a test body;

FIG. 3 illustrates an example of a measurement method;

FIGS. 4A to 4D each illustrate an example of a temperature characteristic of an oscillating frequency of a crystal oscillator;

FIG. 5 is an example of a mounting state of a crystal oscillator;

FIG. 6 is an example of a temperature characteristic of an oscillating frequency of a crystal oscillator;

FIG. 7 is an example of a temperature characteristic of an oscillating frequency of a crystal oscillator;

FIGS. 8A and 8B each illustrate an example of a measurement time of a frequency characteristic of the crystal oscillator; and

FIG. 9 illustrates an example of a measurement system.

### DESCRIPTION OF EMBODIMENTS

A crystal oscillator has a characteristic that changes the oscillating frequency thereof in accordance with the temperature (temperature characteristic of the oscillating frequency).

The types of the crystal oscillators include a simple type designed to achieve low voltage operation and reduce power consumption and a multifunctional type having multiple outputs or enabling optional settings of the frequency. The multifunctional type of crystal oscillators consumes larger power and thus has larger self-generated heat than the simple type. The crystal oscillator having larger self-generated heat is liable to become higher temperature than that at an initial stage of an energization start as time elapses from the energization start. The worse heat dissipation is in the environment in which the crystal oscillator is placed, the more significant elevation of the temperature due to time lapse tends to be.

The temperature characteristic of the oscillating frequency may be grasped with consideration for the heat dissipation in the place where the crystal oscillator is located. However, it may be not inform that the crystal oscillator is placed in the electronic device under an environment having what kind of heat dissipation. In addition, in order to grasp the temperature characteristic of the oscillating frequency with consideration for the heat dissipation, elevation of the temperature due to self-generated heat has to be waited during the test. For this reason, the characteristic at a time immediately after the energization start at which the influence of the self-generated heat is hardly caused may be set to the temperature characteristic of the oscillating frequency.

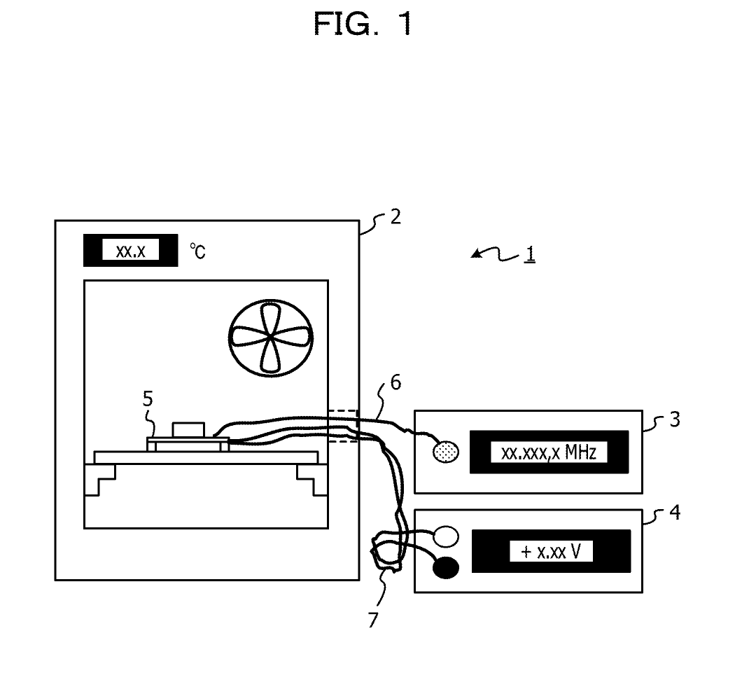

FIG. 1 illustrates an example of a measurement device. In a measurement method, the temperature characteristic of the oscillating frequency of a crystal oscillator is measured. In the measurement method, for example, a measurement device 1 including a temperature test tank 2, a frequency counter 3, and a power source 4, as illustrated in FIG. 1, is used. The temperature test tank 2 includes a volume capable of containing a test device 5 that stores therein the crystal oscillator to be tested and has a heater that increases the temperature inside the tank and a cooling fan that decreases the temperature inside the tank. The frequency counter 3 is a device capable of measuring the frequency of a pulse wave to be input and is coupled to the test device 5 in the temperature test tank 2 with a signal line 6. The power source 4 is a device that supplies power for driving the test device 5 and is coupled to the test device 5 in the temperature test tank 2 with a power source line 7.

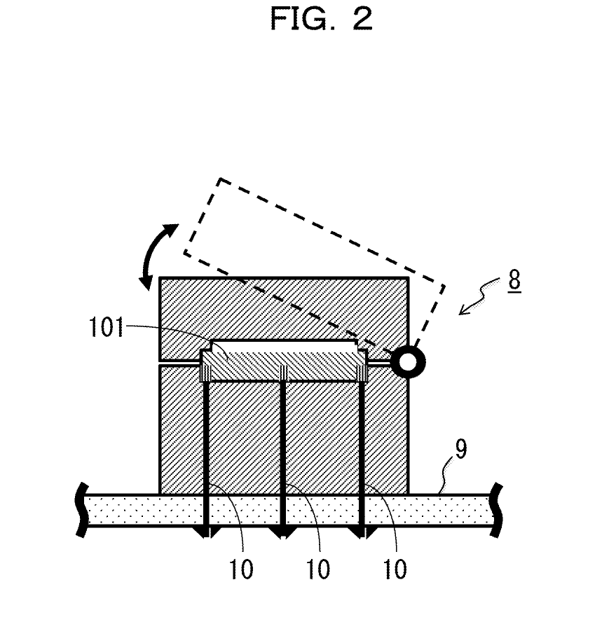

FIG. 2 illustrates an example of a test device. In FIG. 2, the internal structure of the test device 5 is illustrated. The test device 5 includes a socket tool 8 that stores therein a crystal oscillator 101 to be tested and a printed circuit board 9 that mounts thereon the socket tool 8. In the socket tool 8, a contact pin 10 is included that electrically contacts the crystal oscillator 101 to enable energization with the crystal oscillator 101 that serves as a test body without soldering. The crystal oscillator 101 stored in the socket tool 8 is electrically coupled to the signal line 6 and the power source line 7 via the contact pin 10 embedded in the socket tool 8 or circuits of the printed circuit board 9.

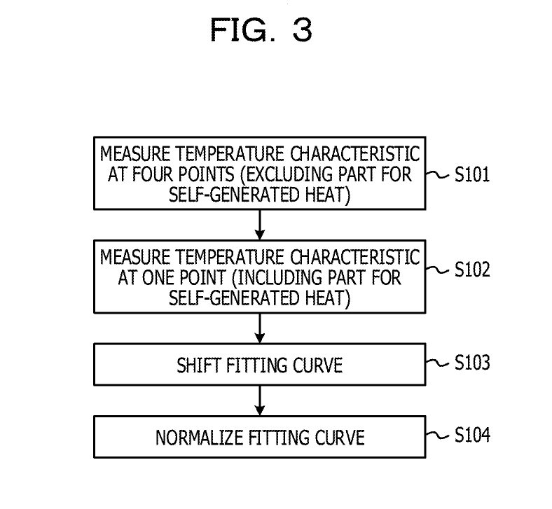

FIG. 3 illustrates an example of a measurement method.

In the measurement method, the temperature characteristic of the oscillating frequency is measured in a state in which the influence of heat self-generated by the crystal oscillator 101 is removed (S101). For example, the crystal oscillator 101 is not energized regularly, but temporarily energized at a point where the temperature around the crystal oscillator 101 inside the temperature test tank 2 is stabled, and the oscillating frequency of the crystal oscillator 101 is measured. For example, the temperature characteristic of the crystal oscillator may be expressed by a cubic function. For this reason, when the oscillating frequency of the crystal oscillator 101 is measured, the measurement is performed at four points with the temperature inside the temperature test tank 2 changed.

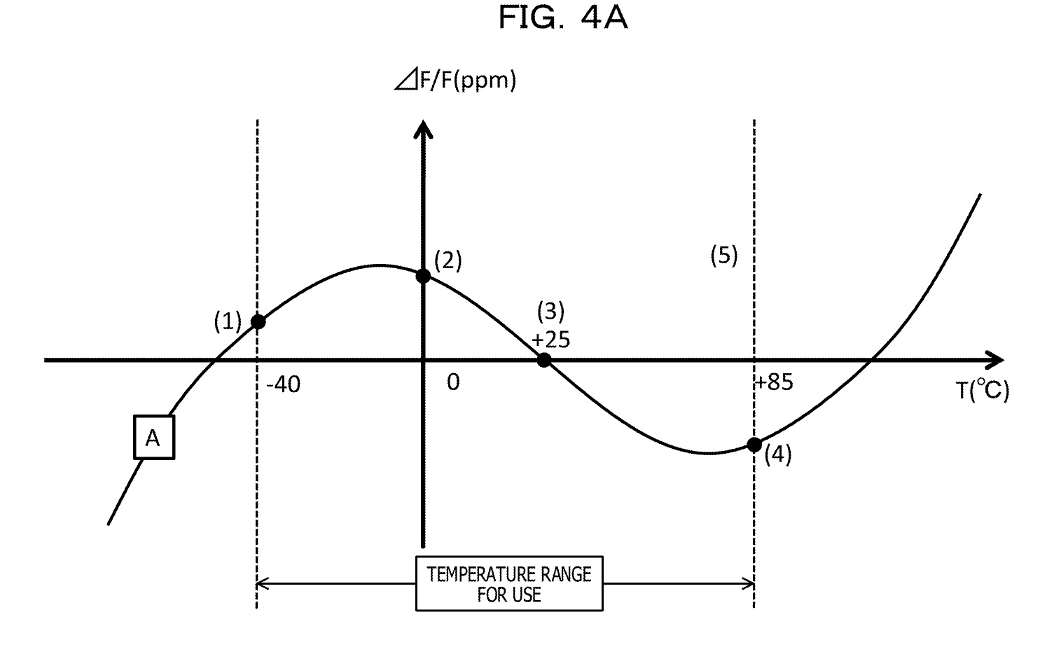

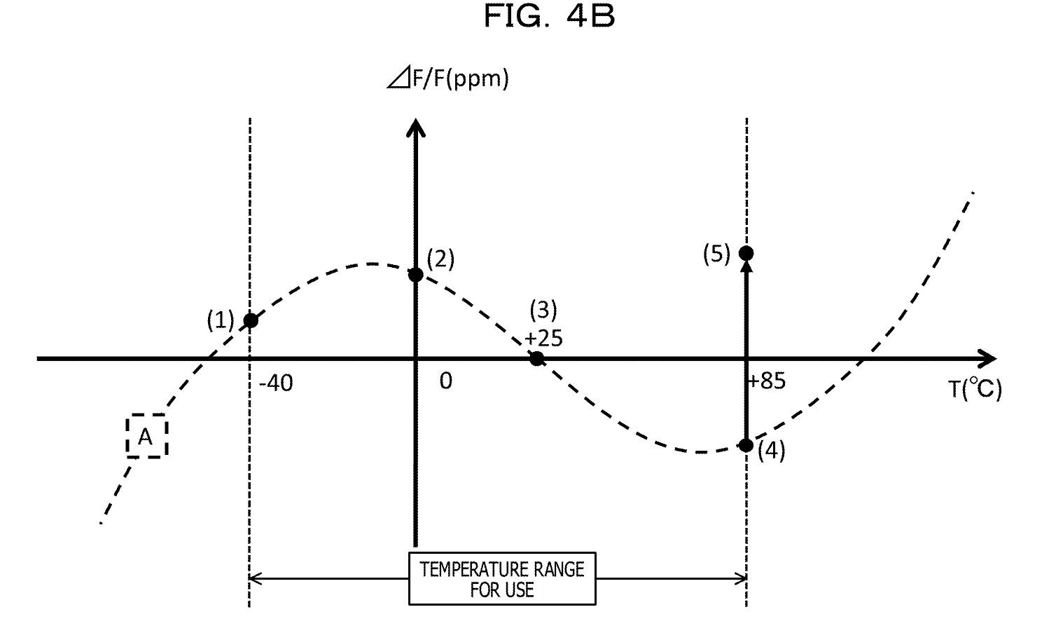

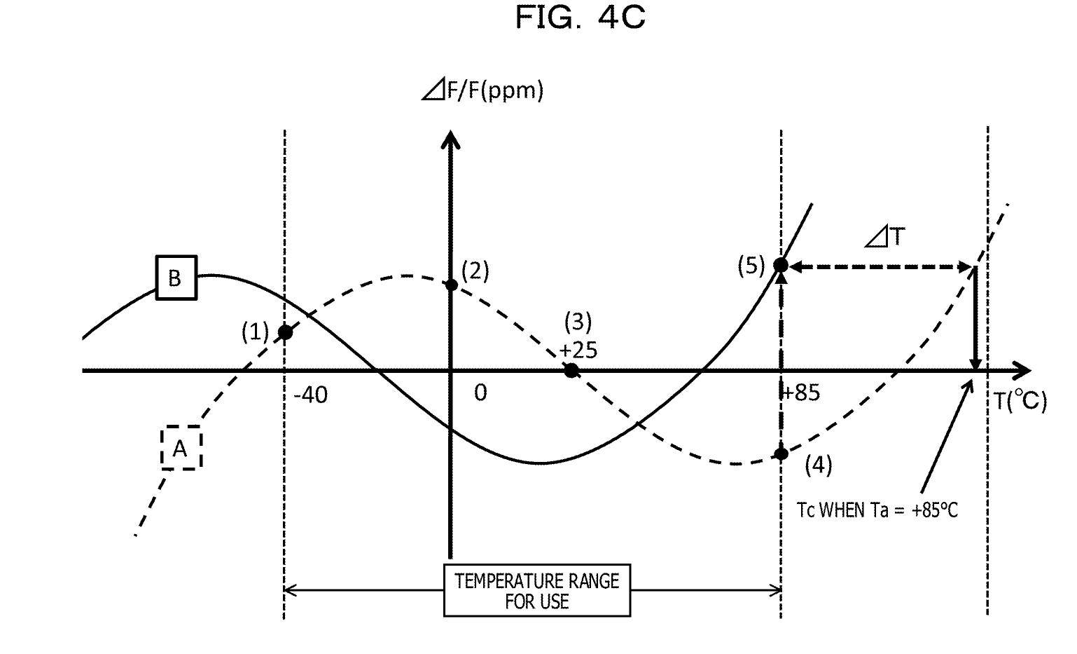

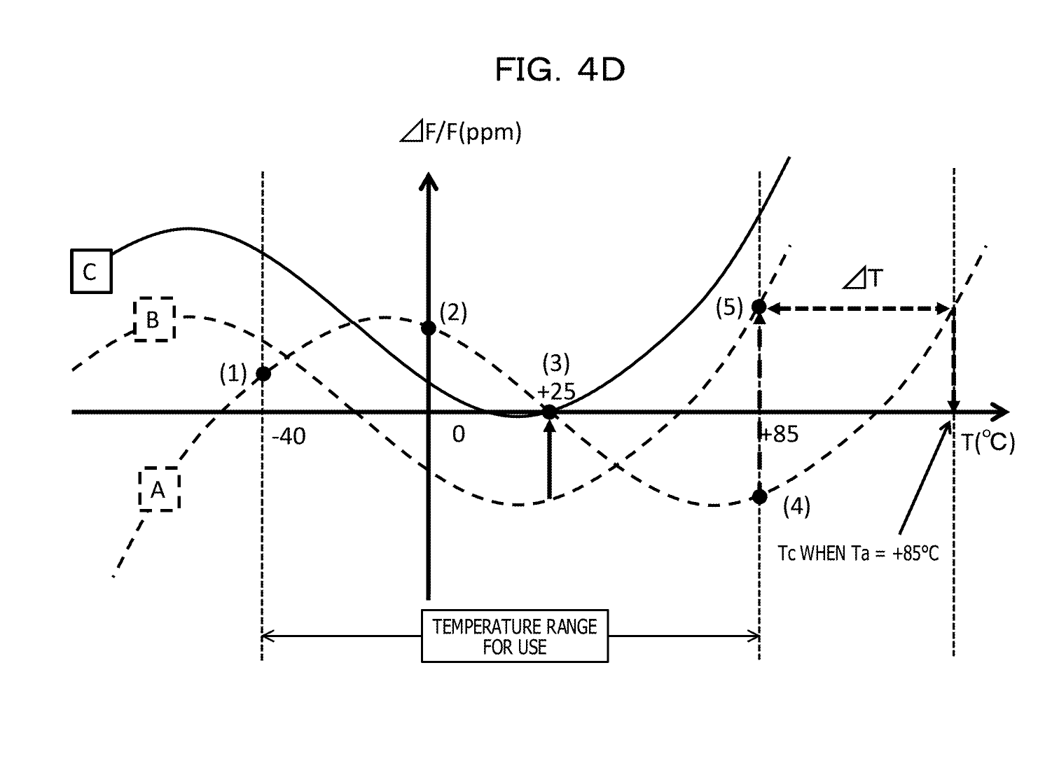

FIGS. 4A to 4D each illustrate an example of a temperature characteristic of an oscillating frequency of a crystal oscillator. FIG. 4A illustrates the temperature characteristic of the oscillating frequency in a state in which the influence of heat self-generated by the crystal oscillator 101 is removed. In FIG. 4A, the vertical axis represents a value obtained by dividing a measured oscillating frequency by a rated oscillating frequency, for example, an oscillating frequency in the case of the reference temperature in design, and the horizontal axis represents a temperature inside the temperature test tank 2. The reference temperature may be 25° C., for example. For example, as illustrated in the graph in FIG. 4A, the oscillating frequency may be measured at four points with the temperatures inside the temperature test tank 2 being −40° C., 0° C., +25° C., and +85° C. In the graph in FIG. 4A, point (1) represents the oscillating frequency with the temperature inside the temperature test tank 2 being −40° C. Point (2) represents the oscillating frequency with the temperature inside the temperature test tank 2 being 0° C. Point (3) represents the oscillating frequency with the temperature inside the temperature test tank 2 being +25° C. Point (4) represents the oscillating frequency with the temperature inside the temperature test tank 2 being +85° C. When the oscillating frequency of the crystal oscillator 101 is measured at four points, a cubic function is obtained that draws a curve fitting the measured values at four points (hereinafter, referred to as “fitting curve A”), for example, a curve as illustrated in the graph in FIG. 4A.

When the crystal oscillator 101 is used in a place where heat dissipation is good, for example, heat self-generated by the crystal oscillator 101 is quickly dissipated. The influence caused by the self-generated heat to the oscillating frequency characteristics thus may be small. For example, electronic devices have been miniaturized and crystal oscillators having high functions and large self-heating amount have been provided. For this reason, use in a place where heat dissipation is not good is desirably assumed.

In the measurement method, after the temperature characteristic of the oscillating frequency in a state in which the influence of heat self-generated by the crystal oscillator 101 is removed is measured, the temperature characteristic assuming a state in which heat is not easily dissipated is measured (S102). For example, after the crystal oscillator 101 which is stored in the socket tool 8 and does not easily dissipate the heat thereof is energized and thermally balanced, the oscillating frequency of the crystal oscillator 101 is measured. For example, as the material of the socket tool 8, when a material having the heat transfer property being inferior to a material having a good heat transfer property, for example a resin, is used, the heat dissipation of the crystal oscillator 101 is decreased.

FIG. 4B illustrates the temperature characteristic of the oscillating frequency in a state in which heat is not easily dissipated. Based on the assumption that a state in which the heat is not easily dissipated is assumed, when the oscillating frequency of the crystal oscillator 101 is measured, it is desirable that the temperature around the crystal oscillator 101 inside the temperature test tank 2 be relatively high. For example, the oscillating frequency when the inside of the temperature test tank 2 is set to +85° C. may be measured. In the graph in FIG. 4B, the oscillating frequency when the temperature inside the temperature test tank 2 is +85° C. is represented by point (5).

FIG. 4C illustrates a graph in which the fitting curve A obtained by operation S101 is shifted along the horizontal axis. After the oscillating frequency when the inside of the temperature test tank 2 is set to +85° C. is measured, a fitting curve (hereinafter, referred to as “fitting curve B”) having the substantially same form as that of the fitting curve A obtained by operation S101 and passing through point (5) is obtained. The fitting curve B is to be obtained by shifting the fitting curve A along the horizontal axis (S103). The shift amount ΔT of the fitting curve may correspond to the differential between the temperature of the crystal oscillator 101 when the self-heating amount is ignored and the temperature of the crystal oscillator 101 when the self-heating amount is included, for example, the differential between the temperature of the crystal oscillator 101 located in a place where heat is not easily dissipated and the temperature of the crystal oscillator 101 located in a place where heat is easily dissipated.

The fitting curve B is obtained by shifting, along the horizontal axis, the fitting curve A obtained with the rated oscillating frequency as the reference. For example, with respect to the fitting curve B with the reference temperature in design of the crystal oscillator 101 of 25° C. and obtained by shifting, along the horizontal axis, the fitting curve A normalized by 25° C. as illustrated in FIG. 4A, various characteristics such as initial deviation and power supply variation characteristics are not set based on the reference temperature in design of 25° C.

In the measurement method, after the fitting curve B is obtained, the fitting curve B is shifted along the vertical axis and a fitting curve (hereinafter, referred to “fitting curve C”) which is normalized by the reference temperature in design of the crystal oscillator 101 is obtained (S104). FIG. 4D illustrates a graph in which the fitting curve B is normalized by the reference temperature in design of the crystal oscillator 101. For example, by shifting the fitting curve B along the horizontal axis so as to pass through a point (the same as point (3)) where ΔF/F becomes zero at 25° C. being the temperature in design of the crystal oscillator 101, the fitting curve illustrated in FIG. 4D is obtained.

According to the fitting curve A illustrated in FIG. 4D, the crystal oscillator 101 exhibits a cubic curve temperature characteristic having a inflection point in the vicinity of +25° C., for example, “good temperature characteristic” when the crystal oscillator 101 is used in a place where heat dissipation is good. When the crystal oscillator 101 is used in a place where heat is not easily dissipated, for example, according to the fitting curve C illustrated in FIG. 4D, the inflection point is shifted to the low-temperature side, whereby a temperature characteristic is exhibited with which the range of the frequency variation is significantly biased. By grasping the temperature characteristic when the crystal oscillator 101 is used in a place where heat is not easily dissipated, specific measures may be taken to enhance the stability of the overall frequency characteristic assuming not only use in a place where heat is easily dissipated but also use in a place where heat is not easily dissipated. For example, measures may be taken such as shifting the frequency characteristic in the direction in which the initial deviation is offset, changing the cut angle of the water, or correcting the position of the inflection point.

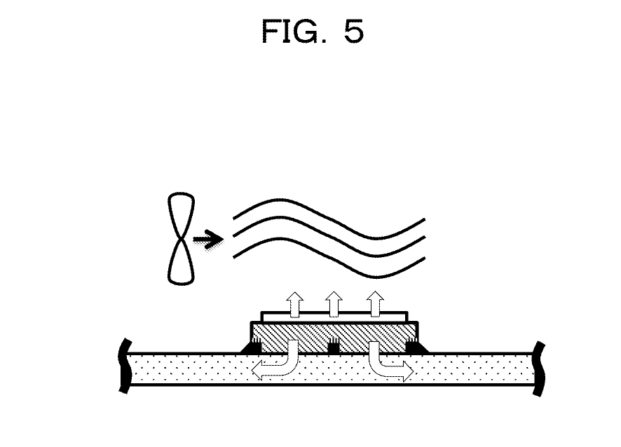

FIG. 5 is an example of a mounting state of a crystal oscillator. A crystal oscillator 102 is mounted on a printed circuit board 109 with soldering. For this reason, the heat of the crystal oscillator 102 mounted on the printed circuit board 109 is dissipated by, for example, heat transfer to the printed circuit board 109, heat transfer to the wind sent by the cooling fan 110 or the like. When a component that becomes high temperature is present around the crystal oscillator 102, the crystal oscillator 102 may be heated. The mounting state of the crystal oscillator gives various thermal influences to the crystal oscillator.

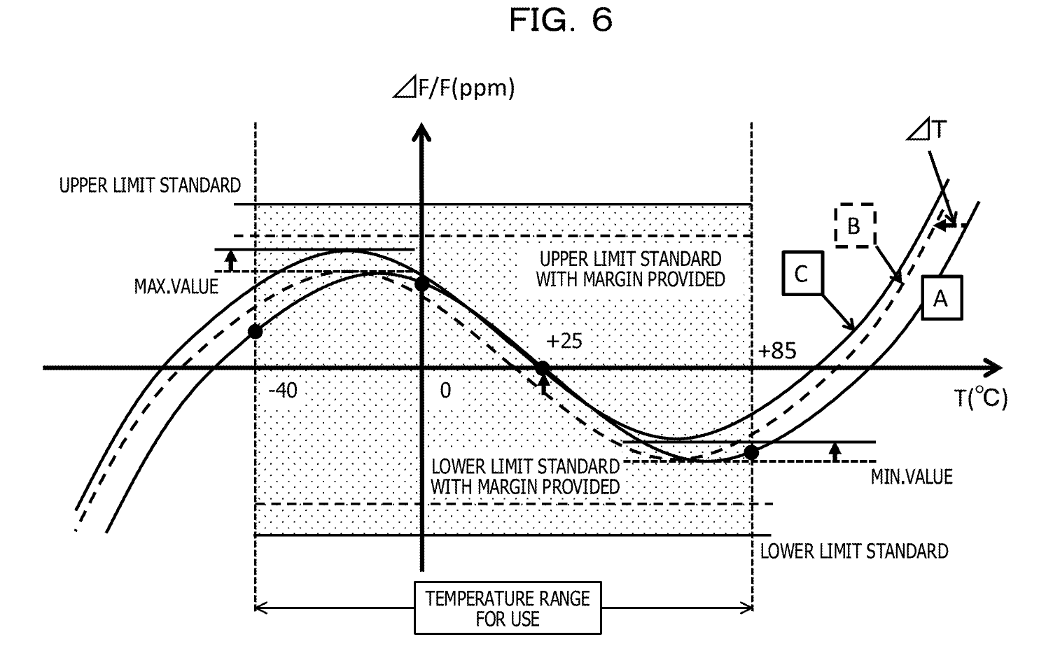

FIG. 6 is an example of a temperature characteristic of an oscillating frequency of a crystal oscillator. In FIG. 6, the temperature characteristic of the oscillating frequency of a crystal oscillator having a small self-generated heat is illustrated. The curve represented by sign A in FIG. 6 illustrates a cubic curve fitted to the oscillating frequency obtained by temporarily energizing the crystal oscillator having a small self-generated heat with the crystal oscillator located in the environments of four temperatures (−40° C., 0° C., +25° C., +85° C.). The curve represented by sign B in FIG. 6 illustrates a cubic curve fitted to the oscillating frequency obtained by maintaining energization of the crystal oscillator having a small self-generated heat with the crystal oscillator located in the environments of four temperatures (−40° C., 0° C., +25° C., +85° C.). The curve represented by sign C in FIG. 6 illustrates a cubic curve obtained by normalizing the curve represented by sign B at +25° C. being the reference temperature. Based on the graph in FIG. 6, in the case of a crystal oscillator having a small self-generated heat, a gap in the temperature characteristic is small between a case when the crystal oscillator is temporarily energized and a case when energization is maintained. For this reason, for example, when the temperature range in which a crystal oscillator having a small self-generated heat is used is set to the range from −40° C. to +85° C., some margin may be provided in setting the upper limit standard and the lower limit standard for the temperature characteristic dispersion of the oscillating frequency.

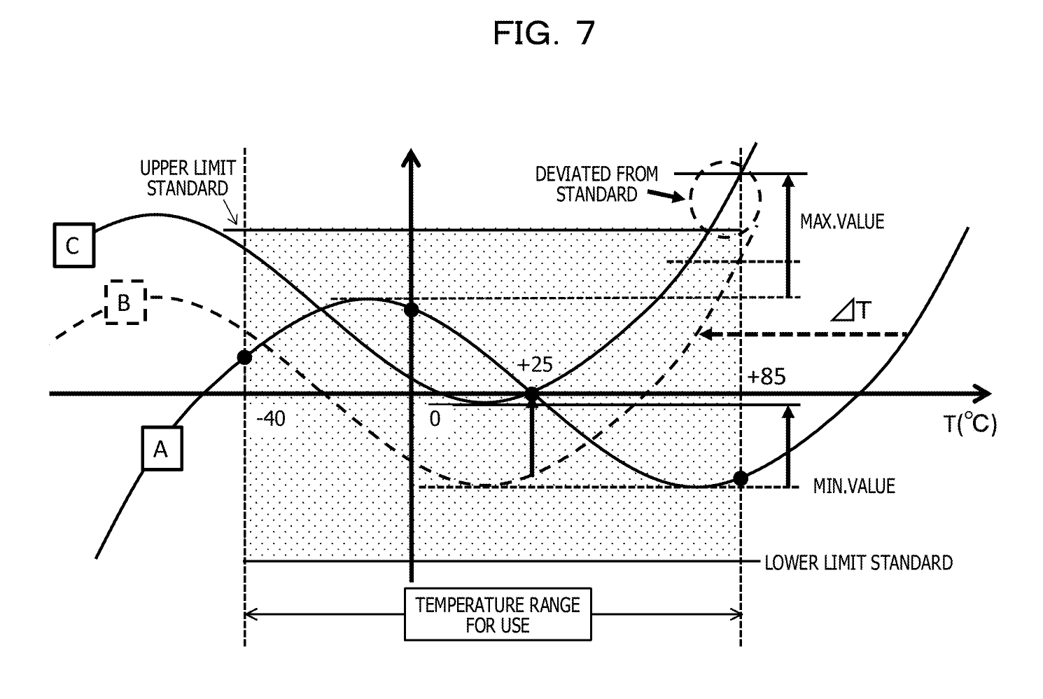

In the case of a crystal oscillator having a large self-generated heat, as illustrated in FIG. 4D, a gap in the temperature characteristic is large between a case when the crystal oscillator is temporarily energized and a case when energization is maintained. FIG. 7 is an example of a temperature characteristic of an oscillating frequency of a crystal oscillator. In FIG. 7, an example of the temperature range for use and an upper limit standard and a lower limit standard for the temperature characteristic dispersion is added to the graph in FIG. 4. Based on the graph in FIG. 7, in the case of a crystal oscillator having a large self-generated heat, a gap in the temperature characteristic is large between a case when the crystal oscillator is temporarily energized and a case when energization is maintained. For this reason, for example, when the temperature range in which a crystal oscillator having a large self-generated heat is used is set to the range from −40° C. to +85° C. and the upper limit standard and the lower limit standard for the temperature characteristic dispersion are set to the same degree with a crystal oscillator having a small self-generated heat, nonstandard parts that deviate from the standard may be caused.

As described above, with a crystal oscillator located in an environment in which the self-generated heat thereof is unignorable, when the crystal oscillator is embedded in an electronic device in accordance with a temperature characteristic in ignorance of the self-generated heat thereof, unexpected problems may be caused. For this reason, for selection of a crystal oscillator, a temperature characteristic may be grasped assuming the actual mounting state thereof. For example, in the action to define a common specification between the side receiving the crystal oscillator and the side producing the crystal oscillator, the relation between the temperature of a component and the oscillating frequency may be actually measured to be identified by attaching a temperature sensor (such as a thermocouple) to the crystal oscillator, for example. In this action, dispersion due to the attaching state of the temperature sensor may be caused, and power consumption during measurement may be increased. Furthermore, this action may not be suitable for a high-accuracy device including a temperature compensation circuit.

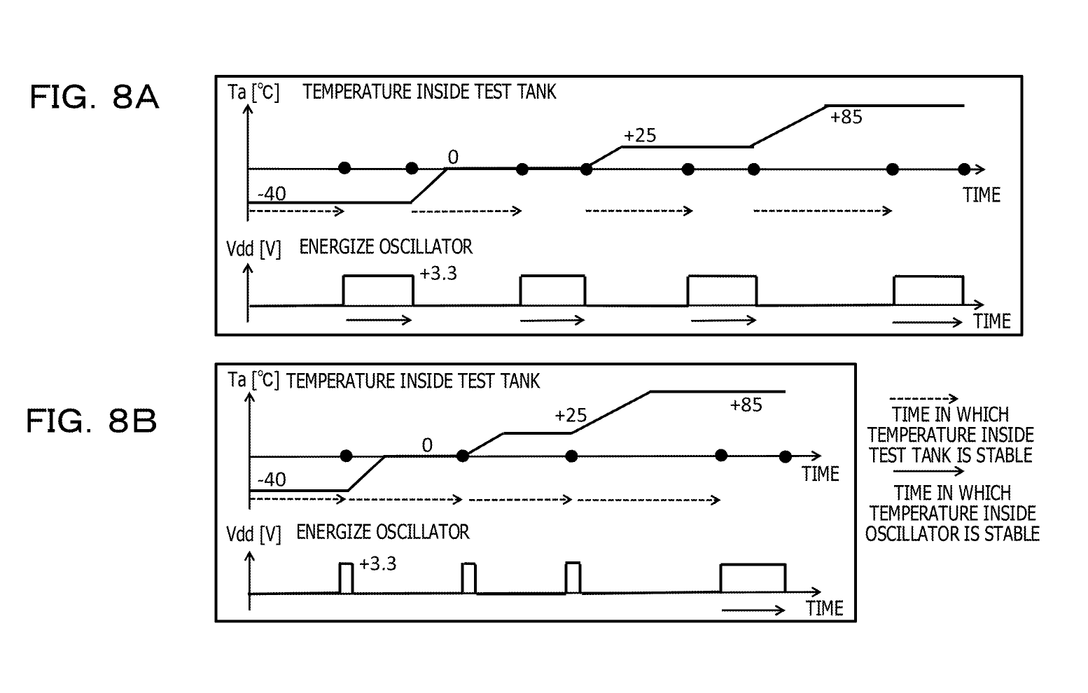

In the measurement method, the temperature characteristic of the oscillating frequency of the crystal oscillator including the influence of self-generated heat may be obtained effectively. FIGS. 8A and 8B each illustrate an example of a measurement time of a frequency characteristic of a crystal oscillator. In FIGS. 8A and 8B, a time is indicated that is taken for measurement of the frequency characteristic of the crystal oscillator with a first measurement method and a second measurement method. In FIG. 8A, a time is indicated that is taken for obtaining the oscillating frequency by changing the temperature inside the temperature test tank to four temperatures (−40° C., 0° C., +25° C., +85° C.) and maintaining energization of the crystal oscillator at each temperature. In FIG. 8B, a time is indicated that is taken for obtaining the oscillating frequency by changing the temperature inside the temperature test tank to three temperatures (−40° C., 0° C., +25° C.) and temporarily energizing the crystal oscillator at each temperature. Thereafter, a time is also indicated that is taken for obtaining the oscillating frequency by changing the temperature inside the temperature test tank to +85° C. and temporarily energizing the crystal oscillator. Thereafter, a time is also indicated that is taken for obtaining the oscillating frequency by maintaining energization after changing to +85° C. Based on comparison between the graph illustrated in FIG. 8A and the graph illustrated in FIG. 8B, in the second measurement method illustrated in FIG. 8B, measurement is completed in a shorter time than that taken in the first measurement method illustrated in FIG. 8A, and the temperature characteristic of the oscillating frequency of the crystal oscillator including the influence of self-generated heat thus may be obtained effectively.

The temperature characteristic of the oscillator frequency may be obtained by changing the inside of the temperature test tank 2 to four temperatures, and the number of times of changing the temperature may be an optional number. The test may be performed with the crystal oscillator 101 placed in the temperature test tank 2. Other devices enabling an appropriate change of the temperature around the crystal oscillator 101 may be used.

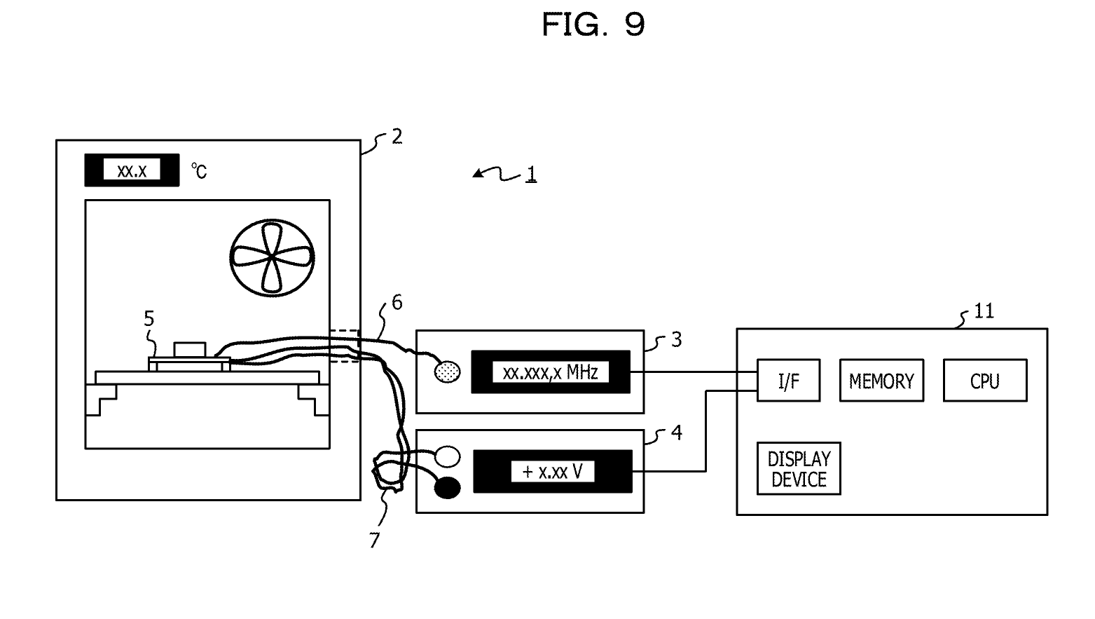

FIG. 9 illustrates an example of a measurement system. In the measurement method described above, for processing of data obtained from the measurement device 1, an all-purpose or dedicated computer 11 including a central processing unit (CPU), a display device, an input device, a memory, or the like may be used, for example. When the computer 11 is used for processing of data obtained from the measurement device 1, the computer may cause the graphs illustrated in FIGS. 4A to 4D to be drawn on the display device or to be output to a peripheral device such as a printer, based on the data obtained from the measurement device 1 through an interface (I/F). When the computer is used for processing of data obtained from the measurement device 1, the computer may obtain measurement data at operation S101 and operation S102, perform processing of operation S103 and operation 104, and output the temperature characteristic of the oscillating frequency of the crystal oscillator including the influence of self-generated heat as illustrated in FIG. 4D. In this case, the computer may read a computer program stored in a storage device and execute the computer program, thereby automatically acquiring measurement data and performing processing of the data, for example. A person performing the test of the crystal oscillator may perform inputs of measurement data and processing of the data using a spreadsheet program or other application.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A measurement method comprising:
obtaining a first temperature characteristic of a crystal oscillator based on a plurality of oscillating frequencies observed when the crystal oscillator is temporarily energized at each of a plurality of temperatures around the crystal oscillator;
observing a first oscillating frequency obtained by maintaining energization of the crystal oscillator after setting the temperature around the crystal oscillator to a first temperature of the plurality of temperatures;
obtaining a second temperature characteristic of a oscillating frequency when energization of the crystal oscillator is maintained based on the first temperature characteristic and the first oscillating frequency; and
normalizing the first temperature characteristic at a given temperature.

2. The measurement method according to claim 1,
wherein the first temperature is the highest temperature among the plurality of temperatures.

3. The measurement method according to claim 1,
wherein the plurality of temperatures are at least four temperatures.

4. The measurement method according to claim 1,
wherein when the first temperature characteristic is obtained, a curve of a temperature characteristic of the crystal oscillator expressed by a cubic function is obtained based on four of the first oscillating frequencies observed when the crystal oscillator is temporarily energized at temperatures at four points of the plurality of temperatures.

5. The measurement method according to claim 1,
wherein a second curve obtained by shifting a first curve of the first temperature characteristic so as to match the first oscillating frequency is set to the second temperature characteristic.

6. The measurement method according to claim 1,
wherein a socket tool that stores the crystal oscillator contains a resin material.

7. A measurement system comprising:
a processor configured to perform a measurement program;
a memory configured to store the measurement program; and
an interface configured to mediate an input and an output of data with a measurement device,
wherein the processor, based on the measurement program,
obtains a first temperature characteristic of the crystal oscillator based on a plurality of oscillating frequencies observed when the crystal oscillator is temporarily energized at each of a plurality of temperatures around the crystal oscillator,
observes a first oscillating frequency obtained by maintaining energization of the crystal oscillator after setting the temperature around the crystal oscillator to a first temperature of the plurality of temperatures,
obtains a second temperature characteristic of an oscillating frequency when energization of the crystal oscillator is maintained based on the first temperature characteristic and the first oscillating frequency, and
normalizes the first temperature characteristic at a given temperature.

8. The measurement system according to claim 7,
wherein the first temperature is the highest temperature among the plurality of temperatures.

9. The measurement system according to claim 7,
wherein the plurality of temperatures are at least four temperatures.

10. The measurement system according to claim 7,
wherein when the first temperature characteristic is obtained, a curve of a temperature characteristic of the crystal oscillator expressed by a cubic function is obtained based on four of the first oscillating frequencies observed when the crystal oscillator is temporarily energized at temperatures at four points of the plurality of temperatures.

11. The measurement system according to claim 7,
wherein a second curve obtained by shifting a first curve of the first temperature characteristic so as to match the first oscillating frequency is set to the second temperature characteristic.

12. The measurement system according to claim 7,
wherein a socket tool that stores the crystal oscillator contains a resin material.
